(19) United States
(12) Patent Application Publication
(10) Pub. No.: US 2025/0337393 A1
(43) Pub. Date: Oct. 30, 2025

(54) INTEGRATOR CIRCUIT WITH TRIMMABLE COMPONENT AND CALIBRATION CONTROL CIRCUIT

(71) Applicant: TEXAS INSTRUMENTS INCORPORATED, Dallas, TX (US)

(72) Inventors: Ramkumar S, Bengaluru (IN); John C. VOGT, Denton, TX (US); Dipankar MANDAL, Bengaluru (IN); Maxim FRANKE, Dallas, TX (US)

(21) Appl. No.: 18/647,401

(22) Filed: Apr. 26, 2024

(51) Int. Cl. H03K 3/011; H03F 3/45

(52) U.S. Cl. CPC H03K 3/011; H03F 3/45475

(57) ABSTRACT

A circuit includes an integrator circuit. The integrator circuit includes: an operational amplifier having an input terminal and an output terminal; a trimmable component having a first terminal, a second terminal, and a control terminal, the first terminal of the trimmable component coupled to the input terminal, and the second terminal of the trimmable component coupled to the output terminal; and a calibration control circuit having a first terminal and a second terminal, the first terminal of the calibration control circuit coupled to the output terminal, and the second terminal of the calibration control circuit coupled to the control terminal of the trimmable component.

### BACKGROUND

Integrator circuits output the time integral of the input signal and have limitations in frequency range and bandwidth. In electronic circuits, capacitors are sometimes used as integrators. An on-chip integrator circuit option may use integrated circuit (IC) components including an operational amplifier with a feedback loop. The on-chip integrator circuit outputs the integral of the input signal over a frequency range based on the circuit time constant and the bandwidth of the operational amplifier. Due to process variation, the time constant of an on-chip integrator circuit may vary by +/−25%, resulting in inaccuracy at the output.

### SUMMARY

In an example, a circuit includes an integrator circuit. The integrator circuit includes: an operational amplifier having an input terminal and an output terminal; a trimmable component having a first terminal, a second terminal, and a control terminal, the first terminal of the trimmable component coupled to the input terminal, and the second terminal of the trimmable component coupled to the output terminal; and a calibration control circuit having a first terminal and a second terminal, the first terminal of the calibration control circuit coupled to the output terminal, and the second terminal of the calibration control circuit coupled to the control terminal of the trimmable component.

In another example, an integrator circuit includes: an operational amplifier having an input terminal and an output terminal; a trimmable capacitor in a feedback loop between the output terminal and the input terminal, the trimmable capacitor having a control terminal; and a calibration control circuit having a first terminal and a second terminal, the first terminal of the calibration control circuit coupled to the output terminal, and the second terminal of the calibration control circuit coupled to the control terminal of the trimmable capacitor. The calibration control circuit is configured to: obtain a ramp time; compare the ramp time to a target time constant to obtain a comparison result; and adjust a control signal provided to the control terminal of the trimmable capacitor responsive to the comparison result.

In yet another example, an apparatus includes an on-chip integrator circuit. The on-chip integrator circuit includes: an operational amplifier having an input terminal and an output terminal; a trimmable component in a feedback loop between the output terminal and the input terminal, the trimmable component having a control terminal; and a calibration control circuit having a first terminal and a second terminal, the first terminal of the calibration control circuit coupled to the output terminal, and the second terminal of the calibration control circuit coupled to the control terminal of the trimmable component. The calibration control circuit is configured to: determine a target value for the trimmable component responsive to a target time constant and test results; and adjust a control signal provided to the control terminal of the trimmable capacitor responsive to the determined target value.

### BRIEF DESCRIPTION OF THE DRAWINGS

FIGS. 1 to 5 are diagrams showing example circuits.

FIG. 6 is a schematic diagram showing example resonant converter circuitry.

FIG. 7 is a schematic diagram showing an example system.

FIG. 8 is a diagram showing control signals and thresholds of an integrator circuit.

FIG. 9 is a graph showing example issues due to integrator time constant variance.

FIG. 10 is a timing diagram showing example calibration timing.

FIG. 11 is a schematic diagram showing example integrator circuitry.

FIG. 12 is a schematic diagram showing an example calibration control circuit.

FIG. 13 is a timing diagram showing example calibration operations.

FIG. 14 is a flowchart showing an example calibration method.

FIG. 15 is a graph showing an example convergence of a ramp time to a target time constant during calibration operations.

### DETAILED DESCRIPTION

The same reference numbers or other reference designators are used in the drawings to designate the same or similar features. Such features may be the same or similar either by function and/or structure.

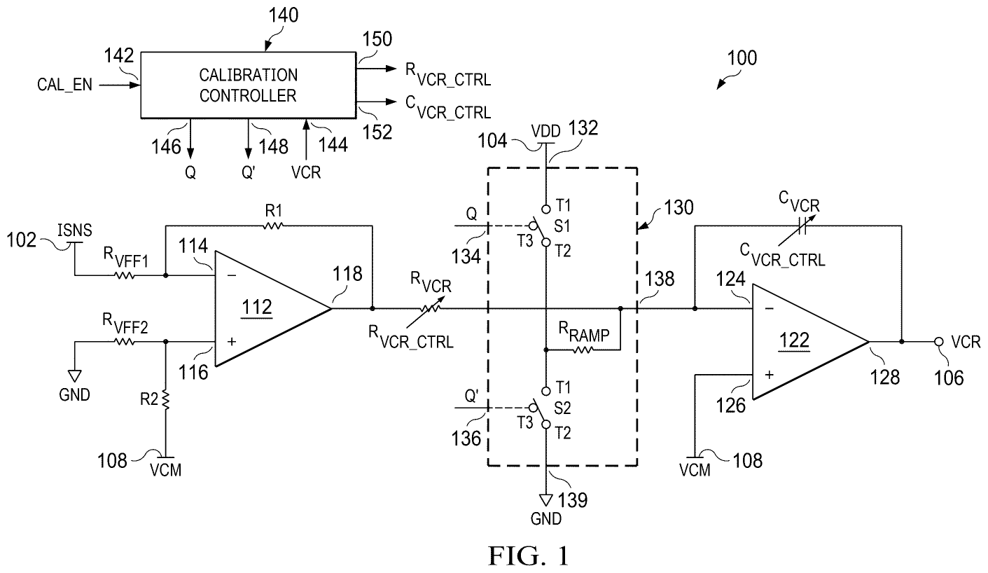

In some examples, an integrator circuit includes: an operational amplifier having an input terminal and an output terminal; a trimmable component having a first terminal, a second terminal, and a control terminal, the first terminal of the trimmable component coupled to the input terminal, and the second terminal of the trimmable component coupled to the output terminal; and a calibration control circuit having a first terminal and a second terminal, the first terminal of the calibration control circuit coupled to the output terminal, and the second terminal of the calibration control circuit coupled to the control terminal of the trimmable component. In some examples, the calibration control circuit performs calibration operations after a power-up sequence and before normal mode operations. Example calibration operations of the calibration control circuit include: determining a target value for the trimmable component responsive to a target time constant and test results; and adjusting a control signal provided to the control terminal of the trimmable capacitor responsive to the determined target value. In some examples, calibration operations of the calibration control circuit include: obtaining a ramp time; comparing the ramp time to a target time constant to obtain a comparison result; and adjusting a control signal provided to the control terminal of the trimmable capacitor responsive to the comparison result. Some integrator circuit examples and related calibration options are described in FIGS. 1 to 15 herein.

FIGS. 1 to 5 are diagrams showing example circuits 100, 200, 300, 400, and 500. In the example of FIG. 1, the circuit 100 has a first terminal 102, a second terminal 104, a third terminal 106, and a fourth terminal 108. The circuit 100 includes a first operational amplifier 112, a second operational amplifier 122, resistors R1, R2, R_{VFF1}, R_{VFF2}, R_{VCR}, and R_{RAMP}, switches S1 and S2, a capacitor C_{VCR}, and a calibration control circuit 140 in the arrangement shown. The first operational amplifier 112, and the resistors R1, R2, R_{VFF1}, R_{VFF2} are components of a gain stage of the circuit 100. The second operational amplifier 122, the resistors R_{VCR}, and R_{RAMP}, the switches S1 and S2, the capacitor C_{VCR}, and the calibration control circuit 140 are components of an integrator stage of the circuit 100. In the example of FIG. 1, the capacitor C_{VCR} and the resistor R_{VCR} are trimmable components of the integrator stage of the circuit 100. As shown, the resistor R_{RAMP} and switches S1 and S2 are components of a calibration ramp circuit 130. In some examples, the circuit 100 is part of a resonant converter controller. In other examples, the circuit 100 may be part of a power converter with charge mode control.

In the example of FIG. 1, the calibration ramp circuit 130 has a first terminal 132, a second terminal 134, a third terminal 136, a fourth terminal 138, and a fifth terminal 139. The first operational amplifier 112 has a first (inverting or “−”) terminal 114, a second (non-inverting or “+”) terminal 116, and a third terminal 118. The second operational amplifier 122 has a first (inverting or “−”) terminal 124, a second (non-inverting or “+”) terminal 126, and a third terminal 128. Each of the resistors R1, R2, R_{VFF1}, R_{VFF2}, and R_{RAMP} has a respective first terminal and a respective second terminal. The resistor R_{VCR} has a first terminal, a second terminal, and a control terminal. Each of the switches S1 and S2 has a first terminal T1, a second terminal T2, and a control terminal T3. The capacitor C_{VCR} has a first terminal, a second terminal, and a control terminal. The calibration control circuit 140 has a first terminal 142, a second terminal 144, a third terminal 146, a fourth terminal 148, a fifth terminal 150, and a sixth terminal 152.

In the example of FIG. 1, the first terminal of the resistor R_{VFF1} is coupled to the first terminal 102 of the circuit 100. The second terminal of the resistor R_{VFF1} is coupled to first terminal 114 of the first operational amplifier 112 and the first terminal of the resistor R1. The second terminal of the resistor R1 is coupled to the third terminal 118 of the first operational amplifier 112. The first terminal of the resistor R_{VFF2} is coupled to ground or a ground terminal. The second terminal of the resistor R_{VFF2} is coupled to second terminal 116 of the first operational amplifier 112 and the first terminal of the resistor R2. The second terminal of the resistor R2 is coupled to the fourth terminal 108 of the circuit 100.

The first terminal of the resistor R_{VCR} is coupled to the third terminal 118 of the first operational amplifier 112. The second terminal of the resistor R_{VCR} is coupled to the fourth terminal 138 of the calibration ramp circuit 130. The first terminal 124 of the second operational amplifier 122 is coupled to the fourth terminal 138 of the calibration ramp circuit 130 and the first terminal of the capacitor C_{VCR}. The second terminal of the capacitor C_{VCR} is coupled to the third terminal 128 of the second operational amplifier 122. The second terminal 126 of the second operational amplifier 122 is coupled to the fourth terminal 108 of the circuit 100. The third terminal of the second operational amplifier 122 is coupled to the third terminal 106 of the circuit 100.

The first terminal 132 of the calibration ramp circuit 130 is coupled to the second terminal 104 of the circuit 100 and to the first terminal T1 of the switch S1. The second terminal T2 of the switch S1 is coupled to the first terminal of the resistor R_{RAMP} and to the first terminal T1 of the switch S2. The control terminal T3 of the switch S1 is coupled to the second terminal 134 of the calibration ramp circuit 130. The second terminal of the resistor R_{RAMP} is coupled to the fourth terminal 138 of the calibration ramp circuit 130. The second terminal T2 of the switch S2 is coupled to the fifth terminal 139 of the calibration ramp circuit 130. The control terminal T3 of the switch S2 is coupled to the third terminal 136 of the calibration ramp circuit 130.

The second terminal 144 of the calibration control circuit 140 is coupled to the third terminal 106 of the circuit 100. The third terminal 146 of the calibration control circuit 140 is coupled to the second terminal 134 of the calibration ramp circuit 130. The fourth terminal 148 of the calibration control circuit 140 is coupled to the third terminal 136 of the calibration ramp circuit 130. The fifth terminal 150 of the calibration control circuit 140 is coupled to the control terminal of the resistor R_{VCR}. The sixth terminal 152 of the calibration control circuit 140 is coupled to the control terminal of the capacitor C_{VCR}.

During normal operations, the circuit 100 is configured to: receive a current sense signal (ISNS) at the first terminal 102; receive a common mode voltage (VCM) at the fourth terminal 108; and provide a capacitor voltage (VCR) at the third terminal 106 responsive to ISNS, VCM, the operations of the first operational amplifier 112 with arrangement of the resistors R1, R2, R_{VFF1}, and R_{VFF2}, and the operations of the second operational amplifier 122 with the arrangement of the capacitor C_{VCR} and the resistor R_{VCR}. During normal operations, the calibration control circuit 140 and the calibration ramp circuit 130 are not used, and VCR is used as part of a control loop (e.g., to regulate on-time or off-time intervals of a switch, to select or change modes, and/or other control loop operations).

During calibration operations, the circuit 100 is configured to: bypass the first operational amplifier 112 (e.g., by connecting the first terminal 102 of the circuit 100 to ground); receive VDD at the second terminal 104; enable the calibration control circuit 140 using a calibration enable signal (CAL_EN); and use the calibration control circuit 140 to perform calibration operations. Example calibration operations of the calibration control circuit 140 include: determining a target value for a trimmable component (e.g., C_{VCR} and/or R_{VCR}) responsive to a target time constant and test results; and adjusting a control signal (R_{VCR}_CTRL and/or C_{VCR}_CTRL) provided to a control terminal of the trimmable component responsive to the determined value. In some examples, the test results are obtained by the calibration control circuit 140 applying Q to the second terminal 134 of the calibration ramp circuit 130 while applying Q′ to the third terminal 136 of the calibration ramp circuit 130.

In some examples, calibration operations of the calibration control circuit 140 include: obtaining a ramp time (e.g., a VCR ramp time) responsive to controlling the calibration ramp circuit 130 to provide up ramp intervals (e.g., switch S1 off and switch S2 on) and/or down ramp intervals (e.g., switch S1 on and switch S2 off); comparing the ramp time to a target time constant to obtain a comparison result; and adjusting a control signal (R_{VCR}_CTRL and/or C_{VCR}_CTRL) provided to the control terminal of the trimmable component (e.g., C_{VCR} and/or R_{VCR}) responsive to the comparison result. In some examples, the calibration control circuit 140 is configured to repeatedly: obtain a ramp time (e.g., a VCR ramp time) responsive to controlling the calibration ramp circuit 130 to provide up ramp intervals (e.g., switch S1 off and switch S2 on) and/or down ramp intervals (e.g., switch S1 on and switch S2 off); compare the ramp time to a target time constant to obtain a comparison result; and adjust a control signal (R_{VCR}_CTRL and/or C_{VCR}_CTRL) provided to the control terminal of the trimmable component (e.g., C_{VCR} and/or R_{VCR}) responsive to the comparison result until the ramp time matches the target time constant to within a target tolerance.

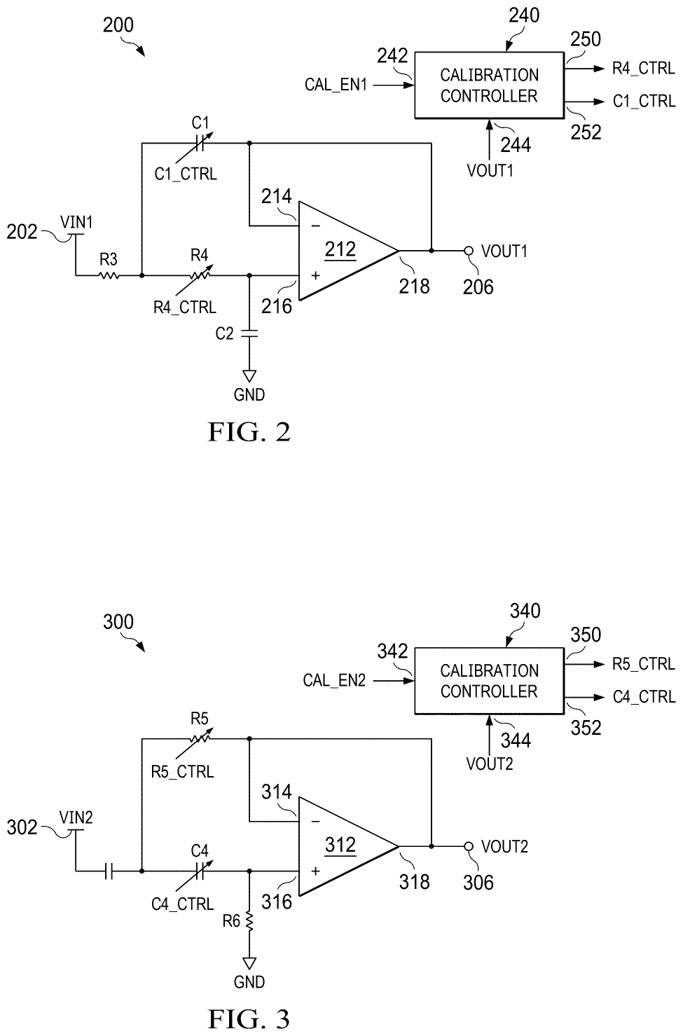

In the example of FIG. 2, the circuit 200 includes an operational amplifier 212, resistors R3 and R4, capacitors C1 and C2, and a calibration control circuit 240 in the arrangement shown. In the example of FIG. 2, the circuit 200 has a first terminal 202 and a second terminal 206. In some examples, the circuit 200 is part of a low-pass filter with an integrator stage. In the example of FIG. 2, the capacitor C1 and the resistor R4 are trimmable components of the integrator stage of the circuit 200.

In the example of FIG. 2, the operational amplifier 212 has a first (inverting or “−”) terminal 214, a second (non-inverting or “+”) terminal 216, and a third terminal 218. The resistor R3 has a first terminal and a second terminal. The resistor R4 has a first terminal, a second terminal, and a control terminal. The capacitor C1 has a first terminal, a second terminal, and a control terminal. The capacitor C2 has a first terminal and a second terminal. The calibration control circuit 240 has a first terminal 242, a second terminal 244, a third terminal 250, and a fourth terminal 252.

In the example of FIG. 2, the first terminal of the resistor R3 is coupled to the first terminal 202 of the circuit 200. The second terminal of the resistor R3 is coupled to first terminal of the resistor R4 and the first terminal of the capacitor C1. The second terminal of the capacitor C1 is coupled to the third terminal 218 of the operational amplifier 212. The second terminal of the resistor R4 is coupled to the second terminal 216 of the operational amplifier 212 and the first terminal of the capacitor C2. The second terminal of the capacitor C2 is coupled to ground or a ground terminal. The second terminal 244 of the calibration control circuit 240 is coupled to the second terminal 206 of the circuit 200. The third terminal 250 of the calibration control circuit 240 is coupled to the resistor R4. The fourth terminal 252 of the calibration control circuit 240 is coupled to the control terminal of the capacitor C1.

During normal operations, the circuit 200 is configured to: receive an input voltage (VIN1) at the first terminal 202; and provide an output voltage (VOUT1) at the second terminal 206 responsive to VIN1 and the operations of the operational amplifier 212 with the arrangement of the capacitors C1 and C2, and the resistors R3 and R4. In some examples, VOUT1 is a filtered version of VIN1 (e.g., VOUT1 does not includes frequencies in VIN1 that are above a threshold). During normal operations, the calibration control circuit 240 is not used, and VOUT1 may be used as part of a signaling chain or control loop, where VOUT1 is a low-pass filter output for VIN1.

During calibration operations, the circuit 200 is configured to: enable the calibration control circuit 240 using a calibration enable signal (CAL_EN1); and use the calibration control circuit 240 to perform calibration operations. Example calibration operations of the calibration control circuit 240 include: determining a target value for a trimmable component (e.g., C1 and/or R4) responsive to a target time constant and test results; and adjusting a control signal (C1_CTRL and/or R4_CTRL) provided to a control terminal of the trimmable component responsive to the determined value.

In some examples, calibration operations of the calibration control circuit 240 include: obtaining a ramp time (e.g., a VOUT1 ramp time); comparing the ramp time to a target time constant to obtain a comparison result; and adjusting a control signal (C1_CTRL and/or R4_CTRL) provided to the control terminal of the trimmable component (e.g., C1 and/or R4) responsive to the comparison result. In some examples, the calibration control circuit 240 is configured to repeatedly: obtain a ramp time (e.g., a VOUT1 ramp time); compare the ramp time to a target time constant to obtain a comparison result; and adjust a control signal (C1_CTRL and/or R4_CTRL) provided to the control terminal of the trimmable component (e.g., C1 and/or R4) responsive to the comparison result until the ramp time matches the target time constant to within a target tolerance.

In the example of FIG. 3, the circuit 300 includes an operational amplifier 312, resistors R5 and R6, capacitors C3 and C4, and a calibration control circuit 340 in the arrangement shown. In the example of FIG. 3, the circuit 300 has a first terminal 302 and a second terminal 306. In some examples, the circuit 300 is part of a high-pass filter with an integrator stage. In the example of FIG. 3, the capacitor C4 and the resistor R5 are trimmable components of the integrator stage of the circuit 300.

In the example of FIG. 3, the operational amplifier 312 has a first (inverting or “−”) terminal 314, a second (non-inverting or “+”) terminal 316, and a third terminal 318. The resistor R5 has a first terminal, a second terminal, and a control terminal. The resistor R6 has a first terminal and a second terminal. The capacitor C3 has a first terminal and a second terminal. The capacitor C4 has a first terminal, a second terminal, and a control terminal. The calibration control circuit 340 has a first terminal 342, a second terminal 344, a third terminal 350, and a fourth terminal 352.

In the example of FIG. 3, the first terminal of the capacitor C3 is coupled to the first terminal 302 of the circuit 300. The second terminal of the capacitor C3 is coupled to the first terminal of the capacitor C4 and the first terminal of the resistor R5. The second terminal of the resistor R5 is coupled to the first terminal 314 and the third terminal 318 of the operational amplifier 312. The second terminal of the capacitor C4 is coupled to the second terminal 316 of the operational amplifier 312 and to the first terminal of the resistor R6. The second terminal of the resistor R6 is coupled to ground or a ground terminal. The second terminal 344 of the calibration control circuit 340 is coupled to the second terminal 306 of the circuit 300. The third terminal 350 of the calibration control circuit 340 is coupled to the control terminal of the resistor R5. The fourth terminal 352 of the calibration control circuit 340 is coupled to the control terminal of the capacitor C4.

During normal operations, the circuit 300 is configured to: receive an input voltage (VIN2) at the first terminal 302; and provide an output voltage (VOUT2) at the second terminal 306 responsive to Vᵢₙ₂ and the operations of the operational amplifier 312 with the arrangement of the capacitors C3 and C4, and the resistors R5 and R6. In some examples, VOUT2 is a filtered version of VIN2 (e.g., VOUT2 does not includes frequencies in VIN2 that are below a threshold). During normal operations, the calibration control circuit 340 is not used, and VOUT2 may be used as part of a signaling chain or control loop, where VOUT2 is a high-pass filter output for VIN2.

During calibration operations, the circuit 300 is configured to: enable the calibration control circuit 340 using a calibration enable signal (CAL_EN2); and use the calibration control circuit 340 to perform calibration operations. Example calibration operations of the calibration control circuit 340 include: determining a target value for a trimmable component (e.g., C4 and/or R5) responsive to a target time constant and test results; and adjusting a control signal (C4_CTRL and/or R5_CTRL) provided to a control terminal of the trimmable component responsive to the determined value.

In some examples, calibration operations of the calibration control circuit 340 include: obtaining a ramp time (e.g., a VOUT2 ramp time); comparing the ramp time to a target time constant to obtain a comparison result; and adjusting a control signal (C4_CTRL and/or R5_CTRL) provided to the control terminal of the trimmable component (e.g., C4 and/or R5) responsive to the comparison result. In some examples, the calibration control circuit 340 is configured to repeatedly: obtain a ramp time (e.g., a VOUT2 ramp time); compare the ramp time to a target time constant to obtain a comparison result; and adjusting a control signal (C4_CTRL and/or R5_CTRL) provided to the control terminal of the trimmable component (e.g., C4 and/or R5) responsive to the comparison result until the ramp time matches the target time constant to within a target tolerance.

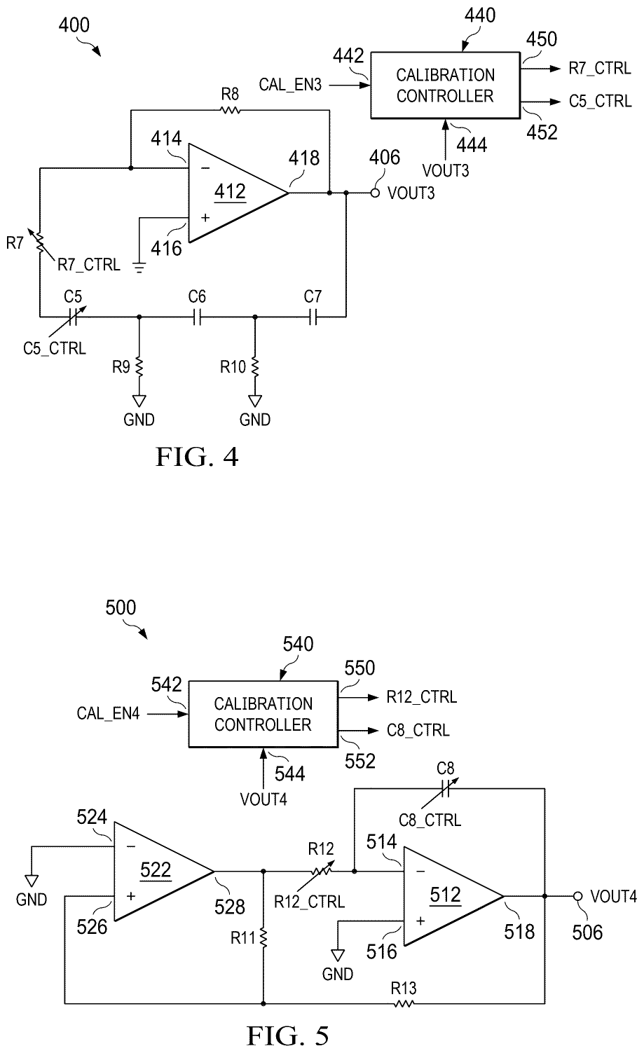

In the example of FIG. 4, the circuit 400 includes an operational amplifier 412, resistors R7 to R10, capacitors C5 to C7, and a calibration control circuit 440 in the arrangement shown. In the example of FIG. 4, the circuit 400 has output terminal 406. In some examples, the circuit 400 is part of a phase-shift oscillator circuit with an integrator stage. In the example of FIG. 4, the capacitor C5 and the resistor R7 are trimmable components of the integrator stage of the circuit 400.

In the example of FIG. 4, the operational amplifier 412 has a first (inverting or “−”) terminal 414, a second (non-inverting or “+”) terminal 416, and a third terminal 418. The resistor R7 has a first terminal, a second terminal, and a control terminal. Each of the resistors R8 to R10 has a respective first terminal and a respective second terminal. The capacitor C5 has a first terminal, a second terminal, and a control terminal. Each of the capacitors C6 and C7 has a respective first terminal and a respective second terminal. The calibration control circuit 440 has a first terminal 442, a second terminal 444, a third terminal 450, and a fourth terminal 452.

In the example of FIG. 4, the first (inverting or “−”) terminal 414 of the operational amplifier 412 is coupled to the first terminal of the resistor R8 and the first terminal of the resistor R7. The second terminal of the resistor R8 is coupled to the third terminal 418 of the operational amplifier 412. The second terminal of the resistor R7 is coupled to the first terminal of the capacitor C5. The second terminal of the capacitor C5 is coupled to the first terminal of the resistor R9 and the first terminal of the capacitor C6. The second terminal of the resistor R9 is coupled to ground or a ground terminal. The second terminal of the capacitor C6 is coupled to the first terminal of the resistor R10 and the first terminal of the capacitor C7. The second terminal of the resistor R10 is coupled to ground or a ground terminal. The second terminal of the capacitor C7 is coupled to the third terminal 418 of the operational amplifier 412. The output terminal 406 of the circuit is also coupled to the third terminal 418 of the operational amplifier.

During normal operations, the circuit 400 is configured to provide an output voltage (VOUT3) at the output terminal 406 responsive to the operations of the operational amplifier 412 with the arrangement of the resistors R7 to R10, and the capacitors C5 to C7. In some examples, VOUT3 has a target frequency. During normal operations, the calibration control circuit 440 is not used, and VOUT3 may be used as an oscillator output with a fixed or tunable frequency.

During calibration operations, the circuit 400 is configured to: enable the calibration control circuit 440 using a calibration enable signal (CAL_EN3); and use the calibration control circuit 440 to perform calibration operations. Example calibration operations of the calibration control circuit 440 include: determining a target value for a trimmable component (e.g., R7 and/or C5) responsive to a target time constant and test results; and adjusting a control signal (R7_CTRL and/or C5_CTRL) provided to a control terminal of the trimmable component responsive to the determined value.

In some examples, calibration operations of the calibration control circuit 440 include: obtaining a ramp time (e.g., a VOUT3 ramp time); comparing the ramp time to a target time constant to obtain a comparison result; and adjusting a control signal (C5_CTRL and/or R7_CTRL) provided to the control terminal of the trimmable component (e.g., C5 and/or R7) responsive to the comparison result. In some examples, the calibration control circuit 440 is configured to repeatedly: obtain a ramp time (e.g., a VOUT3 ramp time); compare the ramp time to a target time constant to obtain a comparison result; and adjusting a control signal (C5_CTRL and/or R7_CTRL) provided to the control terminal of the trimmable component (e.g., C5 and/or R7) responsive to the comparison result until the ramp time matches the target time constant to within a target tolerance.

In the example of FIG. 5, the circuit 500 includes a first operational amplifier 512, resistors R11 to R13, capacitor C8, a second operational amplifier 522, and a calibration control circuit 540 in the arrangement shown. In the example of FIG. 5, the circuit 500 has an output terminal 506. In some examples, the circuit 500 is part of a relaxation oscillator circuit with an integrator stage. In the example of FIG. 5, the capacitor C8 and the resistor R12 are trimmable components of the integrator stage of the circuit 500.

In the example of FIG. 5, the first operational amplifier 512 has a first (inverting or “−”) terminal 514, a second (non-inverting or “+”) terminal 516, and a third terminal 518. The resistor R12 has a first terminal, a second terminal, and a control terminal. Each of the resistors R11 and R13 has a respective first terminal and a respective second terminal. The capacitor C8 has a first terminal, a second terminal, and a control terminal. The second operational amplifier 522 has first (inverting or “−”) terminal 524, a second (non-inverting or “+”) terminal 526, and a third terminal 528. The calibration control circuit 540 has a first terminal 542, a second terminal 544, a third terminal 550, and a fourth terminal 552.

In the example of FIG. 5, the second (non-inverting or “+”) terminal 516 of the first operational amplifier 512 is coupled to the first terminal of the resistor R11 and the first terminal of the resistor R13. The first terminal 514 of the first operational amplifier 512 is coupled to ground or a ground terminal. The second terminal of the resistor R13 is coupled to the third terminal 528 of the second operational amplifier 522. The second terminal of the resistor R11 is coupled to the third terminal 518 of the first operational amplifier 512 and the first terminal of the resistor R12. The second terminal of the resistor R12 is coupled to the first terminal 524 of the second operational amplifier 522 and the first terminal of the capacitor C8. The second terminal of the capacitor C8 is coupled to third terminal 528 of the second operational amplifier 522. The output terminal 506 of the circuit 500 is also coupled to the third terminal 528 of the second operational amplifier 522.

During normal operations, the circuit 500 is configured to provide an output voltage (VOUT4) at the output terminal 506 responsive to the operations of the first operational amplifier 512, and the operations of the second operational amplifier 522 with the arrangement of the resistors R11 to R13, and the capacitor C8. In some examples, VOUT4 has a target frequency. During normal operations, the calibration control circuit 540 is not used, and VOUT4 may be used as part of an oscillator output with a fixed or tunable frequency.

During calibration operations, the circuit 500 is configured to: enable the calibration control circuit 540 using a calibration enable signal (CAL_EN4); and use the calibration control circuit 540 to perform calibration operations. Example calibration operations of the calibration control circuit 540 include: determining a target value for a trimmable component (e.g., R12 and/or C8) responsive to a target time constant and test results; and adjusting a control signal (R12_CTRL and/or C8_CTRL) provided to a control terminal of the trimmable component responsive to the determined value.

In some examples, calibration operations of the calibration control circuit 540 include: obtaining a ramp time (e.g., a VOUT4 ramp time); comparing the ramp time to a target time constant to obtain a comparison result; and adjusting a control signal (C8_CTRL and/or R12_CTRL) provided to the control terminal of the trimmable component (e.g., C8 and/or R12) responsive to the comparison result. In some examples, the calibration control circuit 540 is configured to repeatedly: obtain a ramp time (e.g., a VOUT4 ramp time); compare the ramp time to a target time constant to obtain a comparison result; and adjusting a control signal (C8_CTRL and/or R12_CTRL) provided to the control terminal of the trimmable component (e.g., C8 and/or R12) responsive to the comparison result until the ramp time matches the target time constant to within a target tolerance.

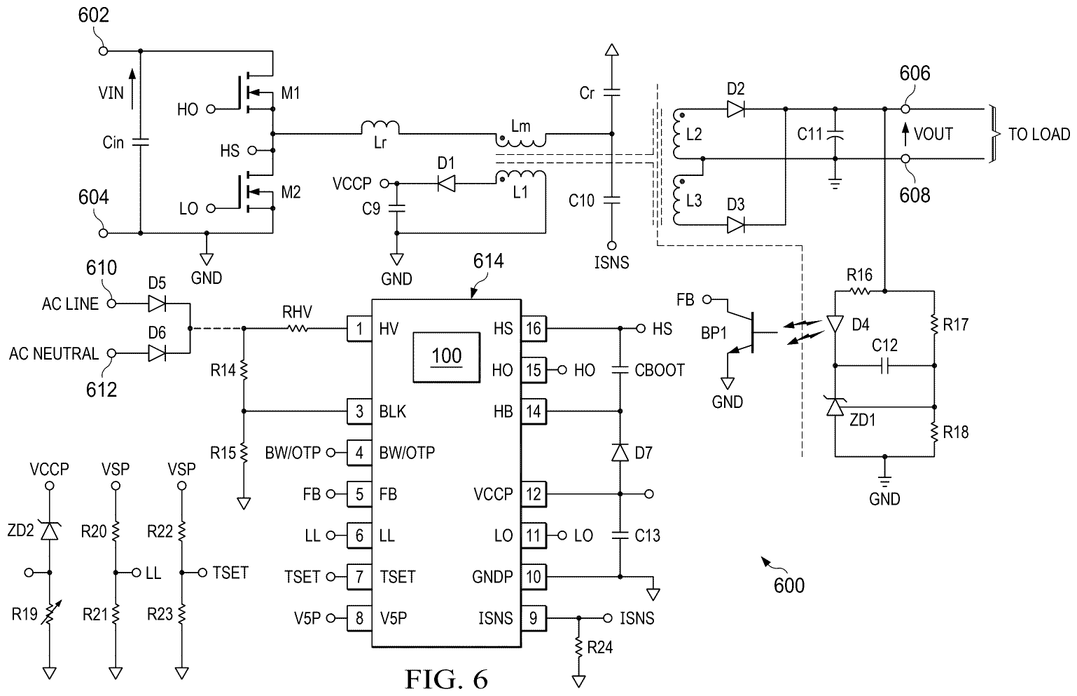

FIG. 6 is a schematic diagram showing example resonant converter circuitry 600. The controller 614 includes the circuit 100 of FIG. 1. In the example of FIG. 6, the resonant converter circuitry 600 has a first terminal 602, a second terminal 604, a third terminal 606, a fourth terminal 608, a fifth terminal 610, and a sixth terminal 612. The resonant converter circuitry 600 includes a capacitors Cin, Cr, CBOOT, and C9 to C13, resistors RVH, R14 to R24, transistors M1 and M2, transistor BP1, inductors Lr, Lm, L1, L2, and L3. diodes D1 to D7, a Zener voltage regulator ZD1, a Zener diode ZD2, and a controller 614 in the arrangement shown. Each of the capacitors Cin, Cr, CBOOT, and C9 to C13 has a respective first terminal and a respective second terminal. Each of the resistors RVH, R14 to R23 has a respective first terminal and a respective second terminal. Each of the transistors M1 and M2, and transistor BP1 has a respective first terminal, a respective second terminal, and a respective control terminal. Each of the inductors Lr, Lm, L1, L2, and L3 has a respective first terminal and a respective second terminal. Each of the diodes D1 to D7 has a respective first terminal and a respective second terminal. The Zener voltage regulator ZD1 has a first terminal, a second terminal, and a control terminal. The Zener diode ZD2 has a first terminal and a second terminal. The controller 614 has terminal 1 (HV), terminal 3 (BLK), terminal 4 (BW/OTP), terminal 5 (FB), terminal 6 (LL), terminal 7 (TSET), terminal 8 (VSP), terminal 9 (ISNS), terminal 10 (GNDP), terminal 11 (LO), terminal 12 (VCCP), terminal 14 (HB), terminal 15 (HO), and terminal 16 (HS).

The first terminal 602 of the resonant converter circuitry 600 is coupled to the first terminal of the capacitor Cin and the first terminal of the transistor M1. The second terminal 604 of the resonant converter circuitry 600 is coupled to the second terminal of the transistor M2 and to ground or a ground terminal. The second terminal of the transistor M1 is coupled to the first terminal of the transistor M2 and to the first terminal of the inductor Lr. The control terminal of the transistor M1 is coupled to terminal 15 of the controller 614 The control terminal of the transistor M2 is coupled to terminal 13 of the controller 614. The second terminal of the inductor Lr is coupled to the first terminal of the inductor Lm. The second terminal of the inductor Lm is coupled to the first terminal of the capacitor Cr and the first terminal of the capacitor C10. The second terminal of the capacitor Cr is coupled to ground or a ground terminal. The second terminal of the capacitor C10 is coupled to terminal 9 of the controller 614. Terminal 9 of the controller 614 is also coupled to the first terminal of the resistor R24. The second terminal of the resistor R24 is coupled to ground or a ground terminal.

In the example of FIG. 6, the inductor L1 is inductively coupled to the inductor Lm. The first terminal of the transistor L1 is coupled to first terminal of the diode D1. The second terminal of the inductor L1 is coupled to ground or a ground terminal. The second terminal of the diode D1 is coupled to the first terminal of the capacitor C9 and to terminal 12 of the controller 614. The second terminal of the capacitor C9 is coupled to ground or a ground terminal. In some examples, the inductor L1, the diode D1, and the capacitor C9 form an auxiliary power supply circuit to power the controller 614. In other examples, the controller 614 may be powered in another way.

The first terminal of the inductor L2 is coupled to the first terminal of the diode D2. The second terminal of the inductor L2 is coupled to the first terminal of the inductor L3 and the fourth terminal 608 of the resonant converter circuitry 600. The second terminal of the inductor L3 is coupled to the first terminal of the diode D3. The second terminal of the diode D2 is coupled to the second terminal of the diode D3, the first terminal of the capacitor C11, the first terminal of the resistor R16, the first terminal of the resistor R17, and the third terminal 606 of the resonant converter circuitry 600. The second terminal of the capacitor C11 is coupled to ground or a ground terminal. The second terminal of the resistor R17 is coupled to the first terminal of the capacitor C12, the first terminal of the resistor R18, and the control terminal of the Zener voltage regulator ZD1. The second terminal of the resistor R18 is coupled to the first terminal of the Zener voltage regulator ZD1. The second terminal of the Zener voltage regulator ZD1 is coupled to the second terminal of the capacitor C12 and the second terminal of the diode D4. The first terminal of the diode D4 is coupled to the second terminal of the resistor R16. In some examples, the diode D4 is a light emitting diode (LED) optically coupled to the transistor BP1. The first terminal of the transistor BP1 is coupled to terminal 5 of the controller 614. The second terminal of the transistor BP1 is coupled to ground or a ground terminal.

The fifth terminal 610 of the resonant converter circuitry 600 is coupled to the first terminal of the diode D5. The sixth terminal 612 of the resonant converter circuitry 600 is coupled to the first terminal of the diode D6. The second terminals of the diodes D5 and D6 are coupled to the first terminal of the resistor RHV and the first terminal of the resistor R14. The second terminal of the resistor RHV is coupled to terminal 1 of the controller 614. The second terminal of the resistor R14 is coupled to the first terminal of the resistor R15 and terminal 3 of the controller 614. The second terminal of the resistor R15 is coupled to ground or a ground terminal.

The first terminal of the Zener diode ZD2 is coupled to terminal 12 of the controller 614. The second terminal of the Zener voltage regulator ZD2 is coupled to the first terminal of the resistor R19. The second terminal of the resistor R19 is coupled to ground or a ground terminal. In some examples, the resistor R19 is a trimmable resistor. In such examples, the value of resistor R19 is adjusted based on a set value for external overtemperature protection. In some examples, the resistors R19 is a negative temperature coefficient (NTC) thermistor. The first terminal of the resistor R20 is coupled to terminal 8 of the controller 614. The second terminal of the resistor R20 is coupled to the first terminal of the resistor R21 and terminal 6 of the controller 614. The second terminal of the resistor R21 is coupled to ground or a ground terminal. The first terminal of the resistor R22 is coupled to terminal 8 of the controller 614. The second terminal of the resistor R22 is coupled to the first terminal of the resistor R23 and terminal 7 of the controller 614. The second terminal of the resistor R23 is coupled to ground or a ground terminal.

In some examples, the terminals of the controller 614 have the name, function, and description provided in Table 1 below.

TABLE 1

| | | Function: | |
|---|---|---|---|
| | | Input(I)/ | |
| | | Output(O)/ | |
| TERMINAL | | Power (P)/ | |
| NAME | NO. | Ground(G) | DESCRIPTION |
| HV | 1 | I | Connects to internal HV startup JFET. This terminal |
| | | | provides start up power for power factor correction and |
| | | | resonant tank circuitry. This terminal may also monitor |
| | | | the AC line voltage for x-capacitor discharge function. |
| BLK | 3 | I | This terminal is used to sense the LLC stage input |
| | | | voltage level. A resistor divider may be used to |
| | | | attenuate the signal before it is applied to this pin. The |
| | | | voltage level on this terminal will determine when the |
| | | | resonant converter starts/stops switching. |
| BW | 4 | I | This terminal is used to sense the output voltage |
| | | | through the bias winding. The sensed voltage is used |
| | | | for output over voltage protection. During startup, the |
| | | | pin is also used to program the ratio between the two |
| | | | burst mode thresholds (BMT_{L} and BMT_{H}). |
| FB | 5 | I | LLC stage control feedback input. The amount of |
| | | | current sourced from this terminal will determine the |
| | | | LLC input power level. |
| LL | 6 | I | The capacitance value connected from this pin to |
| | | | ground will impact the duration of the soft-start period. |
| | | | The resistor divider connected to the pin will define the |
| | | | initial voltage applied on the pin for startup. After |
| | | | system startup, this pin is used to program the burst |
| | | | mode threshold. |
| V5P | 7 | I | 5V bias |
| | | | This pin is externally connected to a decoupling |
| | | | capacitor to GND |
| TSET | 8 | I | Max on time and Integrator Constants programming. |
| | | | PFC On/Off Output or Input. |
| | | | This pin is connected to an external resistor divider. |
| | | | The top of the divider is connected to the 5VP terminal. |
| | | | This voltage of this pin is used to select the maximum |
| | | | on time and internal VCR integrator constants. The |
| | | | programmed is done before the controller enters soft |
| | | | start. After the programming phase has ended, this pin |
| | | | is used to provide PFC on/off logic. |
| ISNS | 9 | I | Resonant current sense. The resonant capacitor |
| | | | voltage is differentiated with a first order filter to |
| | | | measure the resonant current |
| GNDP | 10 | G | Ground reference for all signals. |
| LO | 11 | O | Low-side gate-drive output. |
| VCCP | 12 | P | Regulated 13-V supply. This pin is used to supply the |
| | | | gate driver and power factor correction controller. |
| HB | 14 | I | High-side gate-drive floating supply voltage. The |
| | | | bootstrap capacitor CBOOT is connected between this |
| | | | terminal and the HS terminal. A high voltage, high |
| | | | speed diode should be connected from VCCP to this |
| | | | terminal to supply power to the high-side gate-driver |
| | | | during the period when the low-side MOSFET is |
| | | | conducting. |
| HO | 15 | O | High-side floating gate-drive output. |
| HS | 16 | I | High-side gate-drive floating ground. Current return for |
| | | | the high-side gate-drive current. |

The resonant converter circuitry 600 is configured to: receive VIN across the first terminal 602 and the second terminal 604; and provide VOUT across the third terminal 606 and the fourth terminal 608 responsive to VIN, control of the transistors M1 and M2 by the controller 614, the parameters of the resonant tank formed by the inductor Lr, the inductor Lm, and the capacitor Cr, the operations of the transformer formed by the inductors Lm, L2, and L3, and rectification operations by the diodes D2 and D3.

The controller 614 may perform normal operations and calibration operations with the circuit 100. During normal operations (e.g., when the controller 614 provides CAL_EN with a first state such as a de-asserted state), the circuit 100 operates to: receive ISNS and provide VCR responsive to ISNS, the operations of an on-chip gain stage and the operations of an integrator stage as described in FIG. 1. During normal operations, calibration is not performed and VCR is used as part of a control loop (e.g., to regulate on-time or off-time intervals of a switch, to select or change modes, and/or other control loop operations). During calibration operations (e.g., when the controller 614 provides CAL_EN with a second state such as an asserted state), the circuit 100 operates to calibrate trimmable components of the integrator stage as described in FIG. 1

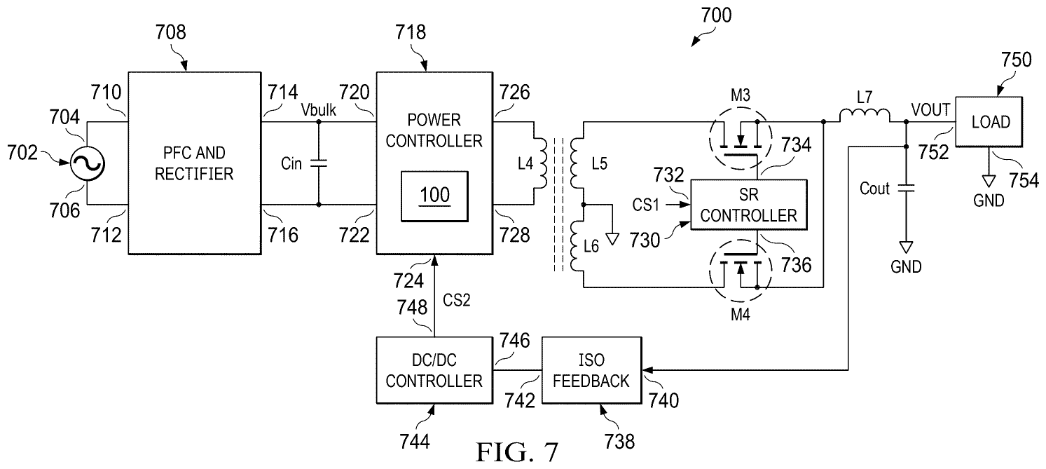

FIG. 7 is a schematic diagram showing an example system 700. In the example of FIG. 7, the system 700 includes an alternating current (AC) source 702, power factor correction (PFC) and rectifier circuitry 708, an input capacitor Cin, a power controller 718, a transformer having inductors L4, L5, and L6, transistors M3 and M4, a synchronous rectifier (SR) controller 730, an inductor L7, an output capacitor Cout, a load 750, isolation feedback circuitry 738, and a direct-current to direct-current (DC/DC) controller 744. In the example of FIG. 7, the input capacitor Cin, a power controller 718, a transformer having inductors L4, L5, and L6, transistors M3 and M4, a synchronous rectifier controller 730, an inductor L7, and an output capacitor Cout are components of resonant converter circuitry. The PFC and rectifier circuitry 708 and the resonant converter circuitry may be part of a power adaptor to power loads such as a television, a monitor, a desktop computer, a laptop, a gaming system, an electronic vehicle, a battery charger, LED lights, and/or other electronic products.

In the example of FIG. 7, the AC source 702 has a first terminal 704 and second terminal 706. The PFC and rectifier circuitry 708 has a first terminal 710, a second terminal 712, a third terminal 714, and a fourth terminal 716. Each of the input capacitor Cin and the output capacitor Cout has a first terminal and a second terminal. The power controller 718 has a first terminal 720, a second terminal 722, a third terminal 724, a fourth terminal 726, and a fifth terminal 728. As shown, the power controller 718 includes the circuit 100 of FIG. 1. Each of the inductors L4 to L7 has a respective first terminal and a respective second terminal. The SR controller 730 has a first terminal 732, a second terminal 734, and a third terminal 736. The load 750 has a first terminal 752 and a second terminal 754. The isolation feedback circuitry 738 has a first terminal 740 and a second terminal 742. The DC/DC controller 744 has a first terminal 746 and a second terminal 748.

The first terminal 704 of the AC source 702 is coupled to the first terminal 710 of the PFC and rectifier circuitry 708. The second terminal 706 of the AC source 702 is coupled to the second terminal 712 of the PFC and rectifier circuitry 708. The third terminal 714 of the PFC and rectifier circuitry 708 is coupled to the first terminal of the input capacitor Cin and the first terminal 720 of the power controller 718. The fourth terminal 716 of the PFC and rectifier circuitry 708 is coupled to the second terminal of the input capacitor Cin and the second terminal 722 of the power controller 718. The third terminal 724 of the power controller is coupled to the second terminal 748 of the DC/DC converter 744. The fourth terminal 726 of the power controller 718 is coupled to the first terminal of the inductor L4. The fifth terminal 728 of the power controller 718 is coupled to the second terminal of the inductor L4. The first terminal of the inductor L5 is coupled to the first terminal of the transistor M3. The second terminal of the inductor L5 is coupled to the first terminal of the inductor L6 and to ground or a ground terminal. The second terminal of the inductor L6 is coupled to the first terminal of the transistor M4. The second terminals of the transistors M3 and M4 are coupled to the first terminal of the inductor L7. The control terminal of the transistor M3 is coupled to the second terminal 734 of the SR controller 730. The control terminal of the transistor M4 is coupled to the third terminal 736 of the SR controller 730. The second terminal of the inductor L7 is coupled to the first terminal of the output capacitor Cout, the first terminal 752 of the load 750, and the first terminal of the isolation feedback circuitry 738. The second terminal 754 of the load 750 is coupled to ground or a ground terminal. The second terminal of the output capacitor Cout is also coupled to ground or a ground terminal. The second terminal 742 of the isolation feedback circuitry 738 is coupled to the first terminal 746 of the DC/DC controller 744.

The AC source 702 is configured to output an AC voltage. The PFC and rectifier circuitry 708 is configured to: receive the AC voltage across the first terminal 710 and the second terminal 712; perform power factor correction on the AC voltage; rectify the power factor corrected AC voltage; and provide the rectified voltage as a DC voltage (Vbulk) across third terminal 714 and the fourth terminal 716. The input capacitor Cin operates to smooth changes to Vbulk. The power controller 718 is configured to: receive Vbulk across the first terminal 720 and the second terminal 722; receive a control signal (CS2) at the third terminal 724; and provide voltage across the fourth terminal 726 and the fifth terminal 728 responsive to Vbulk and CS2. In some examples, the power controller 718 includes the transistor M1 and M2, a resonant tank (e.g., Lr, Lm, and Cr in FIG. 6), and a controller (e.g., the controller 614 in FIG. 6). The inductors L4, L5, and L6 perform transformer operations. The transistors M3 and M4 and the SR controller 730 operate to rectify the voltage across the inductors L5 and L6. The inductor L7 operates to transfer energy from the transistors M3 and M4 to the output capacitor Cout, resulting in an output voltage VOUT. The load 750 receives VOUT and performs operations responsive to VOUT. The isolation feedback circuitry 738 is configured to: receive the output voltage VOUT at the first terminal 740; and provide a related sense signal at the second terminal 742. The DC/DC controller 744 is configured to: receive the sense signal from the isolation feedback circuitry 738 at the first terminal 746; and provide CS2 at the second terminal 748 responsive to the sense signal.

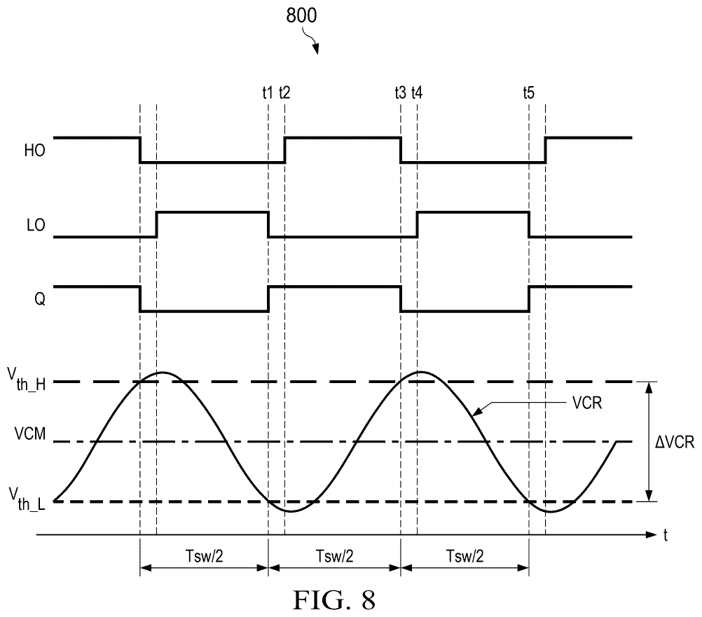

FIG. 8 is a diagram showing control signals and thresholds of an integrator circuit. In the diagram 800 of FIG. 8, example waveforms for HO, LO, Q, VCM, and VCR are provided. An upper threshold V_{th_H} and a lower threshold V_{th_L} are also shown in the diagram 800. The difference between V_{th_H} and V_{th_L} is given as ΔVCR. As shown, VCR is centered around VCM. When HO is asserted, VCR ramps up. When LO is asserted VCR ramps down. In the example of FIG. 8, HO and Q are de-asserted at the same time and are asserted at different times. As shown, the period of Q is the switching frequency period (T_{SW})/2, where T_{SW} is the frequency at which the transistors M1 and M2 are operated. Also, Q has a 50% duty cycle in the example of FIG. 8. As shown, HO and Q are de-asserted when VCR reaches V_{th_H}. After a brief interval (e.g., from time t₃ to time t₄), LO is asserted. When VCR reaches V_{th_L}, LO is de-asserted and Q is asserted. After a brief interval (e.g., from time t₁ to time t₂), HO is asserted.

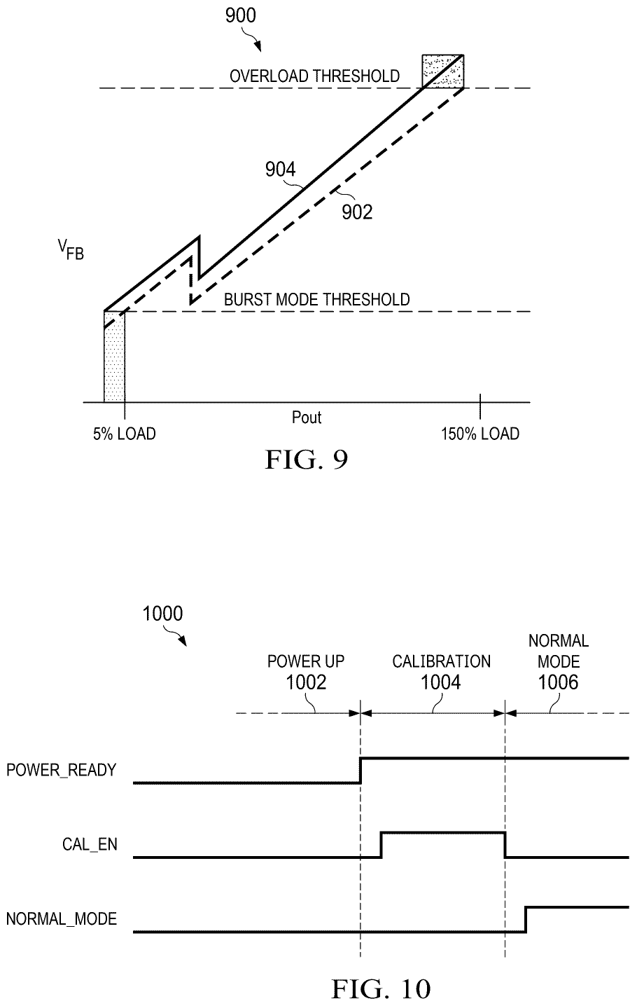

In some examples, ΔVCR=V_{th_H}−V_{th_L}=FB. Any mismatch in R_{VCR} or C_{VCR} leads to a direct mismatch in FB versus Isns_{avg} from part to part and hence mismatch in FB versus the output power Pout. FIG. 9 is a graph 900 showing example issues due to integrator time constant variance. In the example of FIG. 9, the graph 900 shows FB waveforms 902 and 904 for two controllers, where FB is charted as a function of Pout. In some examples, operations of a controller (e.g., the controller 614 in FIG. 6 or a similar controller included with the power controller 718 in FIG. 7) are based on the value of FB. If the value of FB varies for different controllers due to integrator circuit inaccuracies, the different controllers may reach an overload threshold and/or a burst mode threshold at different times. In the example of FIG. 9, the FB waveform 902 for a first controller reaches an overload threshold at approximately 120% load while the FB waveform 904 for a second controller reaches an overload threshold at approximately 150% load. Also, the FB waveform 902 results in the first controller operating in a burst mode below a 5% load as intended. In contrast, the FB waveform 904 results in the second controller having premature entry to an overload condition and not operating in a burst mode

FIG. 10 is a timing diagram 1000 showing example calibration timing. The timing diagram 1000 includes a power up interval 1002, a calibration interval 1004, and a normal mode interval 1006. In the example of FIG. 10, the power up interval 1002 ends and the calibration interval begins when a Power_ready signal is asserted (e.g., when VDD and/or other voltages reach a target threshold). Once the calibration interval 1004 begins, CAL_EN is asserted. The calibration interval 1004 ends and the normal mode begins responsive to calibration being completed and CAL_EN being de-asserted. In the normal mode interval 1006, a normal_mode signal is asserted to begin normal operation (e.g., normal operations of the circuits 100, 200, 300, 400, or 500 in FIGS. 1 to 5). In some examples, there may be a brief delay between the calibration interval 1004 starting and CAL_EN being asserted. Also, there may be a brief delay between the normal mode interval starting and Normal_mode being asserted.

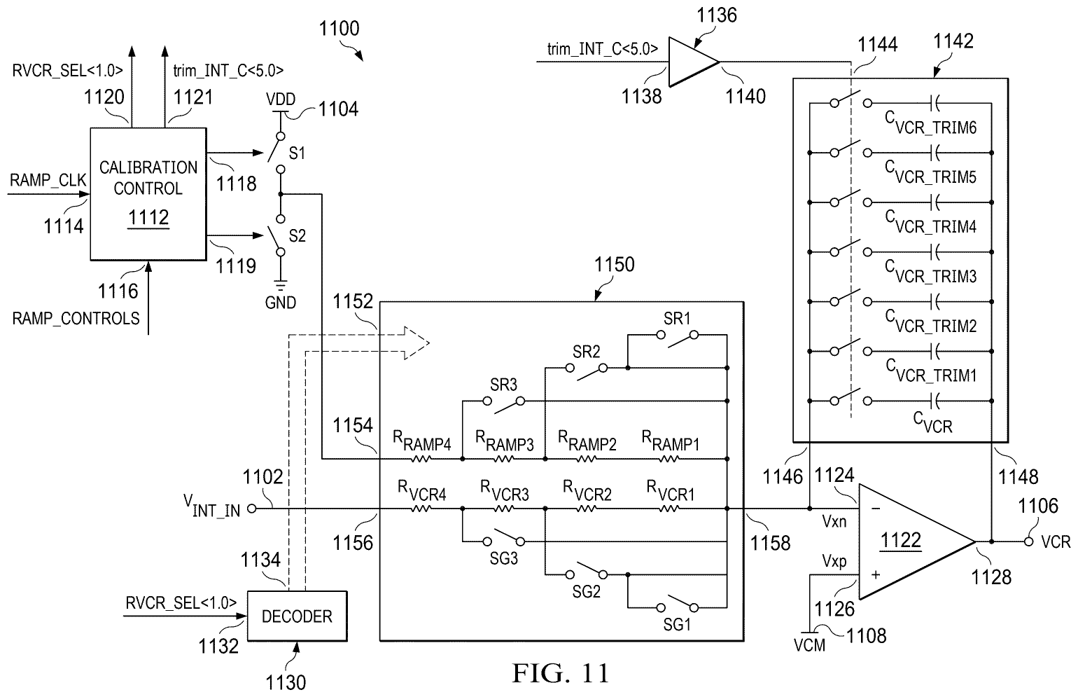

FIG. 11 is a schematic diagram showing example integrator circuitry 1100. The integrator circuitry 1100 is an example of the integrator circuitry or integrator stage in FIG. 1. As shown, the integrator circuitry 1100 has a first terminal 1102, a second terminal 1104, a third terminal 1106, and a fourth terminal 1108. The integrator circuitry 1100 includes a calibration control circuit 1112, the switches S1 and S2, trimmable resistors 1150, a trimmable capacitor 1142, an operational amplifier 1122, decoder circuitry 1130, and buffer circuitry 1136.

The calibration control circuitry 1112 has a first terminal 1114, second terminals 1116, a third terminal 1118, a fourth terminal 1119, a fifth terminal 1120, and a sixth terminal 1121. The decoder 1130 has a first terminal 1132 and second terminals 1134. The trimmable resistors 1150 has a first terminal 1152, a second terminal 1154, a third terminal 1156, and a fourth terminal 1158. In the example of FIG. 11, the trimmable resistors 1150 include a set or R_{RAMP} resistors R_{RAMP1} to R_{RAMP4} and related switches SR1 to SR3. The trimmable resistors 1150 also include a set of R_{VCR} resistors R_{VCR1} to R_{VCR4} and related switches SG1 to SG3. The buffer circuitry 1136 has a first terminal 1138 and a second terminal 1140. The trimmable capacitor 1142 has a first terminal 1144, a second terminal 1146, and a third terminal 1148. In the example of FIG. 11, the trimmable capacitor 1142 includes a set of capacitors C_{VCR} and C_{VCR1} to C_{VCR6} and related switches. The operational amplifier 1122 has a first (inverting or “−”) terminal 1124, a second (non-inverting or “+”) terminal 1126, and a third terminal 1128.

The first terminal 1102 of the integrator circuitry 1100 is coupled to the third terminal 1156 of the trimmable resistors 1150. The second terminal 1154 of the trimmable resistors 1150 is coupled to the second terminal of the switch S1 and the first terminal of the switch S2. The first terminal 1152 of the trimmable resistors 1150 is coupled to the second terminal 1134 of the decoder circuitry 1130. The first terminal 1132 of the decoder circuitry 1130 is coupled to the fifth terminal 1120 of the calibration control circuit 1112. The fourth terminal 1158 of the trimmable resistors 1150 is coupled to the first terminal 1124 of the operational amplifier 1122 and the second terminal 1146 of the trimmable capacitor 1142. The second terminal 1126 of the operational amplifier 1122 is coupled to the fourth terminal 1108 of the integrator circuitry 1100 and receives VCM. The third terminal 1128 of the operational amplifier 1122 is coupled to the third terminal 1148 of the trimmable capacitor 1142 and the third terminal 1106 of the integrator circuitry 1100. The first terminal 1144 of the trimmable capacitor 1142 is coupled to the second terminal 1140 of the buffer circuitry 1136. The first terminal 1138 of the buffer circuitry is coupled to the sixth terminal 1121 of the calibration control circuit 1112. The third terminal 1118 of the calibration control circuit 1112 is coupled to the control terminal of the switch S1. The fourth terminal 1119 of the calibration control circuit 1112 is coupled to the control terminal of the switch S2. The first terminal 1114 of the calibration control circuit 1112 is coupled to a ramp clock source and receives RAMP_CLK. The second terminals 1116 of the calibration control circuit 1112 receives ramp control signals (e.g., CAL_EN, VCR, and/or other control signals).

During normal operations, the integrator circuitry 1100 is configured to: receive an input signal V_{INT_IN} at the first terminal 1102; receive VCM at the fourth terminal 1108; and provide VCR at the third terminal 1106 responsive to V_{INT_IN}, VCM, and the operations of the operational amplifier 1122 with arrangement of the resistors of the trimmable resistors 1150 and the trimmable capacitor 1142. In some examples, V_{INT_IN} is ISNS or an amplified version of ISNS (e.g., the output of the gain state of the circuit 100 in FIG. 1). During normal operations, the calibration control circuit 1112 and the switches S1 and S2 are not used, and VCR is used as part of a control loop (e.g., to regulate on-time or off-time intervals of a switch, to select or change modes, and/or other control loop operations).

During calibration operations, the integrator circuitry 1100 is configured to: receive VDD at the second terminal 1104; enable the calibration control circuit 1112 using a calibration enable signal (e.g., CAL_EN); and use the calibration control circuit 1112 to perform calibration operations. Example calibration operations of the calibration control circuit 1112 include: determining a target value for a trimmable component (e.g., the trimmable resistors 1150 and/or the trimmable capacitor 1142) responsive to a target time constant and test results; adjusting a first control signal (e.g., RVCR_SEL<1:0> or related decoded signal herein) to the trimmable resistors 1150 responsive to the determined value; adjusting a second control signal (e.g., trim_INT_C<5:0> or related buffered signal herein) to the trimmable capacitor 1142 responsive to the determined value. In some examples, calibration operations of the calibration control circuit 1112 include: obtaining a ramp time (e.g., a VCR ramp time) responsive to controlling the switches S1 and S2 to provide up ramp intervals (e.g., switch S1 off and switch S2 on) and/or down ramp intervals (e.g., switch S1 on and switch S2 off); comparing the ramp time to a target time constant to obtain a comparison result; adjusting the first control signal (RVCR_SEL<1:0>) provided to the trimmable resistors 1150 responsive to the comparison result; and adjusting the second control signal (trim_INT_C<5:0>) to the trimmable capacitor 1142 responsive to the comparison result. In some examples, the calibration control circuit 1112 is configured to repeatedly: obtain a ramp time (e.g., a VCR ramp time) responsive to controlling the switches S1 and S2 to provide up ramp intervals (e.g., switch S1 off and switch S2 on) and/or down ramp intervals (e.g., switch S1 on and switch S2 off); compare the ramp time to a target time constant to obtain a comparison result; adjusting the first control signal (RVCR_SEL<1:0>) provided to the trimmable resistors 1150 responsive to the comparison result; and adjusting the second control signal (trim_INT_C<5:0>) to the trimmable capacitor 1142 responsive to the comparison result until the VCR ramp time matches the target time constant to within a target tolerance.

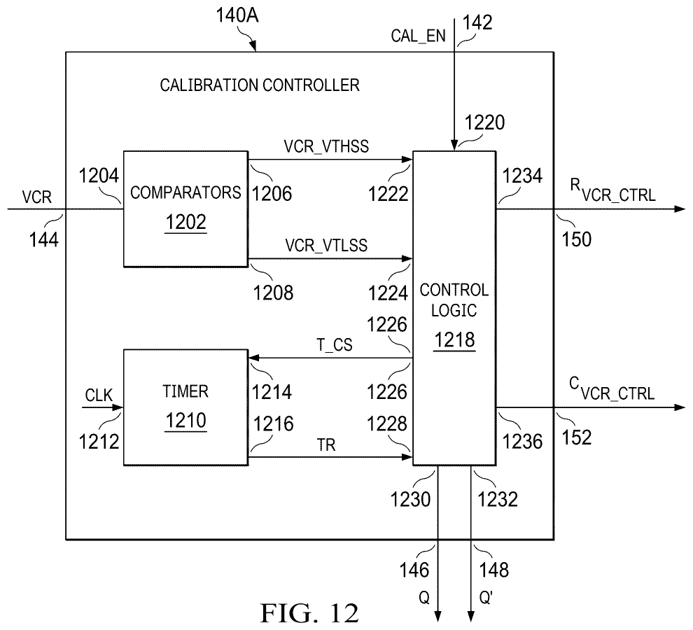

FIG. 12 is a schematic diagram showing an example calibration control circuit 130A. The calibration control circuit 140A is an example of the calibration control circuits 140 in FIG. 1 or the calibration control circuit 1112 in FIG. 11. As shown, the calibration control circuit 140A has the first terminal 142, the second terminal 144, the third terminal 146, the fourth terminal 148, the fifth terminal 150, and the sixth terminal 152 described in FIG. 1. In the example of FIG. 12, the calibration control circuit 140A includes comparators 1202, a timer 1210, and control logic 1218. The comparators 1202 have a first terminal 1204, a second terminal 1206, and a third terminal 1208. The timer 1210 has a first terminal 1212, a second terminal 1214, and a third terminal 1216. The control logic 1218 has a first terminal 1220, a second terminal 1222, a third terminal 1224, a fourth terminal 1226, a fifth terminal 1228, a sixth terminal 1230, and seventh terminal 1232, an eighth terminal 1234, and a ninth terminal 1236.

The first terminal 1204 of the comparators 1202 is coupled to the second terminal 144 of the calibration control circuit 140A. The second terminal 1206 of the comparators 1202 is coupled to the second terminal 1222 of the control logic 1218. The third terminal 1208 of the comparators 1202 is coupled to the third terminal 1224 of the control logic 1218. The first terminal 1212 of the timer 1210 is coupled to a clock signal (CLK) source and receives CLK. The second terminal 1214 of the timer 1210 is coupled to the fourth terminal 1226 of the control logic 1218. The third terminal 1216 of the timer 1210 is coupled to the fifth terminal 1228 of the control logic 1218. The first terminal 1220 of the control logic 1218 is coupled to the first terminal 142 of the calibration control circuit 140A. The sixth terminal 1230 of the control logic 1218 is coupled to the third terminal 146 of the calibration control circuit 140A. The seventh terminal 1232 of the control logic 1218 is coupled to the fourth terminal 148 of the calibration control circuit 140A. The eighth terminal 1234 of the control logic 1218 is coupled to the fifth terminal 150 of the calibration control circuit 140A. The ninth terminal 1236 of the control logic 1218 is coupled to the sixth terminal 152 of the calibration control circuit 140A.

In operation, the calibration control circuit 140A may be enabled or disabled based on CAL_EN. When enabled, the calibration control circuit 140A is configured to provide Q at the third terminal 146 and Q′ at the fourth terminal 148 to control the switches S1 and S2, resulting in VCR up ramps and VCR down ramps being provided by an integrator circuit to the second terminal 144. When a VCR up ramp reaches an upper threshold (e.g., V_{th_H}), the comparators 1202 outputs an upper threshold reach trigger (VCR_VTHSS) at the second terminal 1206. When a VCR down ramp reaches a low threshold (e.g., V_{th_L}), the comparators 1202 outputs a lower threshold reach trigger (VCR_VTLSS) at the third terminal 1208.

During testing, the control logic 1218 is configured to: receive VCR_VTHSS at the second terminal 1222; provide a timer control signal (T_CS) at the fourth terminal 1226 responsive to VCR_VTHSS being asserted; receive VCR_VTLSS at the third terminal 1224; store a first time as the time between VCR_VTHSS being asserted and VCR_VTLSS being asserted; receive another VCR_VTHSS at the second terminal 1222; store a second time as the time between VCR_VTLSS being asserted and VCR_VTHSS; combine the first time and the second time; and provide timer results (TR) at the third terminal 1216 responsive to the first time and the second time. In different examples, multiple timers may be used. As another option, only the first time or the second time may be used as the timer results.

The control logic 1218 is configured to: receive the timer results at the fifth terminal 1228; compare the timer results to a target time constant to obtain a comparison results; adjust R_{VCR}_CTRL at the eighth terminal 1234 responsive to the comparison results; and adjust C_{VCR}_CTRL at the ninth terminal 1236 responsive to the comparison results. The calibration operations of the calibration control circuit 140A may be repeated as needed until the timer results from the timer 1210 are aligned with the target time constant. In some examples, the target time constant is predetermined and stored in memory of the control logic 1218.

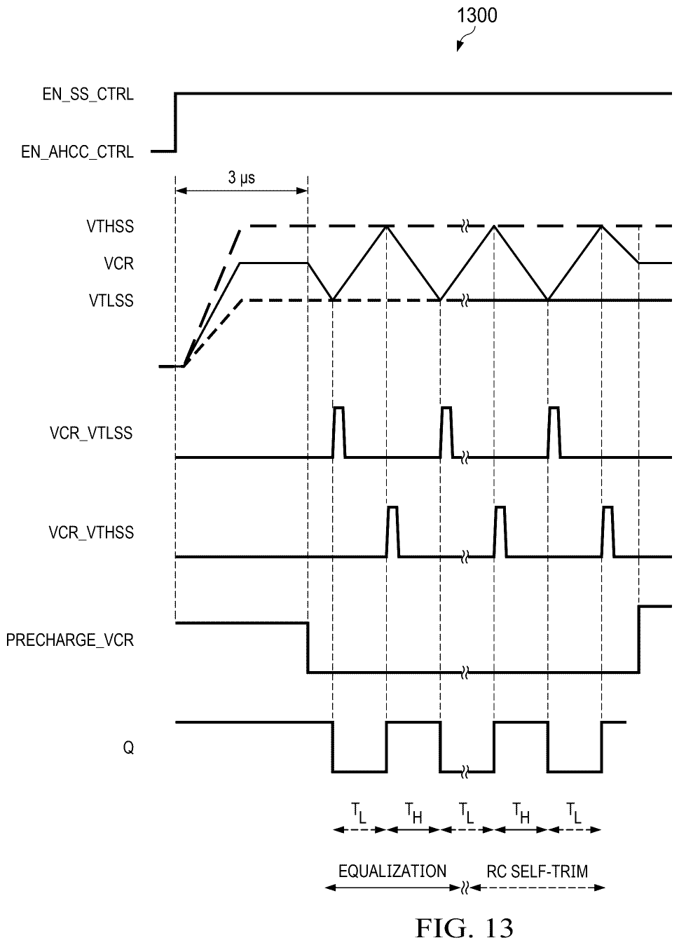

FIG. 13 is a timing diagram 1300 showing example calibration operations. In the timing diagram 1300, example waveforms are provided for CAL_EN, V_{th_H}, VCR, V_{th_L}, VCR_VTLSS, VCR_VTHSS, a pre-charge signal (precharge_vcr), and Q (the control signal for switches of the calibration ramp circuit). In the example of FIG. 13, precharge_vcr sets the internal voltage of integrator and feedback capacitor to a target level. In the timing diagram 1300, calibration operations begin responsive to CAL_EN being asserted. After CAL_EN is asserted, VCR, V_{th_H}, and V_{th_L} rise to a default level during a pre-charge interval (e.g., 3 us). After the pre-charge interval is done, precharge_vcr is de-asserted and down ramps and up ramps are applied to the integrator circuit by a calibration ramp circuit. The result of applying down ramps and up ramps to the integrator circuit is VCR ramping down and ramping up between V_{th_H} and V_{th_L}. When VCR reaches V_{th_H}, VCR_VTHSS is asserted and Q is asserted. When VCR reaches V_{th_L}, VCR_VTLSS is asserted and Q is de-asserted. In some examples, Q (and Q′) is used to control switches of a calibration ramp circuit to obtain a VCR ramp time. In different examples, the VCR ramp time may measure: the time between VCR_VTLSS being asserted and VCR_VTHSS being asserted; the time between VCR_VTHSS being asserted and VCR_VTLSS being asserted; the time between VCR_VTLSS being asserted and a subsequent VCR_VTLSS being asserted; or the time between VCR_VTHSS being asserted and a subsequent VCR_VTHSS being asserted. In some examples, calibration operations include an equalization interval and a trim interval. During the equalization interval, a calibration control circuit equalizes the up ramp time (T_{L} or Ton herein) and the down ramp time (T_{H} or Toff herein). During the trim interval, trimmable components of an integrator circuit are trimmed and a resulting VCR ramp time is compared to a target time constant. The process is repeated until the trimmed components result in VCR ramp time that is aligned with the target time constant to within a target tolerance.

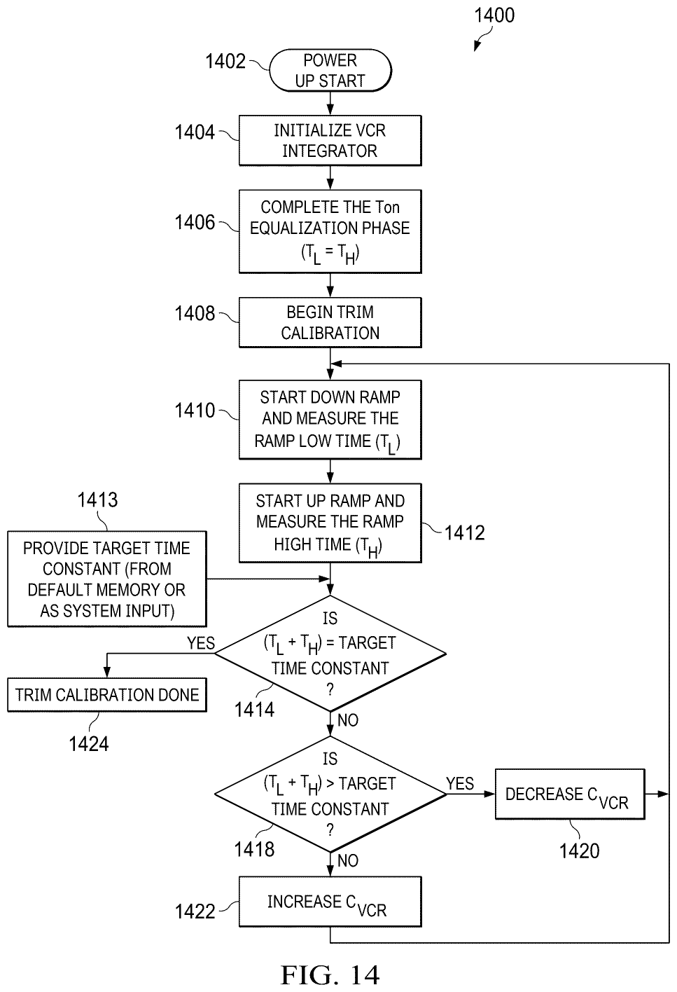

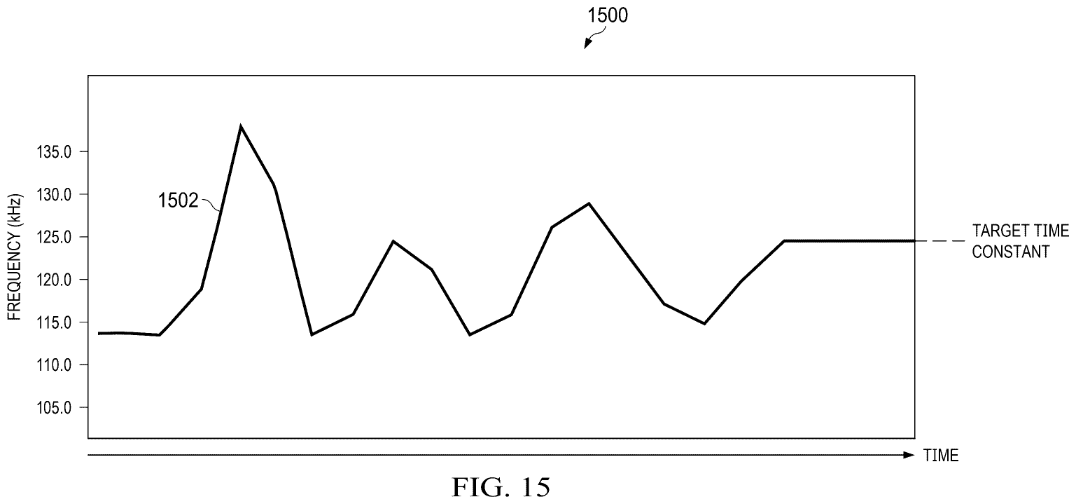

FIG. 14 is a flowchart showing an example calibration method 1400. The calibration method 1400 may be performed, for example, by the calibration control circuits 140, 240, 340, 440, 540 in FIGS. 1 to 5, the controller 614 of FIG. 6, the power controller 718 of FIG. 7, the calibration control circuit 1112 of FIG. 11, the calibration control circuit 140A of FIG. 12. As shown, the calibration method 1400 includes power up at block 1402. At block 1404, a VCR integrator is initialized. At block 1406, an on-time (Ton) equalization phase is completed so that VCR up ramps and VCR down ramps are equalized (e.g., T_{L}=T_{H} in FIG. 14). At block 1408, trim operations begin. At block 1410, a down ramp starts and the ramp low time (T_{L}) is measured. At block 1412, an up ramp starts and the ramp high time (T_{H}) is measured. A block 1413, a target time constant is provided. For example, the target time constant may be obtained from a memory or as a system input. If T_{L}+T_{H} equals a target time constant (block 1414), trim calibration is done at block 1424. If T_{L}+T_{H} is greater than the target time constant (block 1418), C_{VCR} is decreased at block 1420. If T_{L}+T_{H} is not greater than the target time constant (block 1418), C_{VCR} is increased at block 1422. After block 1422 or block 1420, the calibration method 1400 returns to block 1410.

FIG. 15 is a graph 1500 showing an example convergence of ramp time 1502 to a target time constant during calibration operations. In the example of FIG. 15, the ramp time 1502 (e.g., a VCR ramp time) is adjusted up and down by adjusting the control signals for one or more trimmable components of an integrator circuit. Once the ramp time 1502 aligns with a target time constant, calibration is complete.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A circuit comprising:
an integrator circuit including:
an operational amplifier having an input terminal and an output terminal;
a trimmable component having a first terminal, a second terminal, and a control terminal, the first terminal of the trimmable component coupled to the input terminal, and the second terminal of the trimmable component coupled to the output terminal; and
a calibration control circuit having a first terminal and a second terminal, the first terminal of the calibration control circuit coupled to the output terminal, and the second terminal of the calibration control circuit coupled to the control terminal of the trimmable component.

2. The circuit of claim 1, wherein the integrator circuit includes a calibration ramp circuit having a first terminal and a second terminal, the second terminal of the calibration ramp circuit coupled to the input terminal of the operational amplifier.

3. The circuit of claim 1, wherein the input terminal is an inverting terminal and the trimmable component is a capacitor.

4. The circuit of claim 3, wherein the operational amplifier has a non-inverting terminal, the trimmable component is a first trimmable component, the integrator circuit includes a second trimmable component between the output terminal and the inverting terminal or the non-inverting terminal, and the second trimmable component is a resistor.

5. The circuit of claim 4, wherein the operational amplifier has an inverting terminal, the trimmable component is a first trimmable component, the integrator circuit includes a second trimmable component between the output terminal and the inverting terminal or the non-inverting terminal, and the second trimmable component is a resistor.

6. The circuit of claim 1, wherein the calibration control circuit includes a timer and a comparator, and the timer is configured to track an amount of clock cycles from a trigger until the comparator indicates a ramp voltage reaches a threshold.

7. The circuit of claim 6, wherein the calibration control circuit is configured to compare the amount of clock cycles to a target amount of clock cycles for a predetermined time constant.

8. The circuit of claim 6, wherein the comparator is a first comparator, the calibration control circuit includes a second comparator, and the timer is configured to track the amount of clock cycles from the first comparator indicating the ramp voltage reaches a first threshold until the second comparator indicates the ramp voltage reach a second threshold.

9. The circuit of claim 6, wherein the calibration control circuit includes storage coupled to the timer, the storage configured to store a target time constant or a related number of clock cycles.

10. An integrator circuit comprising:
an operational amplifier having an input terminal and an output terminal;
a trimmable capacitor in a feedback loop between the output terminal and the input terminal, the trimmable capacitor having a control terminal; and
a calibration control circuit having a first terminal and a second terminal, the first terminal of the calibration control circuit coupled to the output terminal, and the second terminal of the calibration control circuit coupled to the control terminal of the trimmable capacitor, the calibration control circuit configured to:
obtain a ramp time;
compare the ramp time to a target time constant to obtain a comparison result; and
adjust a control signal provided to the control terminal of the trimmable capacitor responsive to the comparison result.

11. The integrator circuit of claim 10, wherein the calibration control circuit is configured to:
measure an up ramp time;
measure a down ramp time; and
combine the up ramp time and the down ramp time to obtain the ramp time.

12. The integrator circuit of claim 10, wherein the calibration control circuit is configured to:
adjust the control signal to increase capacitance of the trimmable capacitor responsive to the comparison result indicating the ramp time is less than the target time constant; and
adjust the control signal to decrease capacitance of the trimmable capacitor responsive to the comparison result indicating the ramp time is more than the target time constant.

13. The integrator circuit of claim 10, wherein the calibration control circuit is configured to obtain the target time constant from memory.

14. An apparatus comprising:
an on-chip integrator circuit including:
an operational amplifier having an input terminal and an output terminal;
a trimmable component in a feedback loop between the output terminal and the input terminal, the trimmable component having a control terminal; and
a calibration control circuit having a first terminal and a second terminal, the first terminal of the calibration control circuit coupled to the output terminal, and the second terminal of the calibration control circuit coupled to the control terminal of the trimmable component, the calibration control circuit configured to:
determine a target value for the trimmable component responsive to a target time constant and test results; and
adjust a control signal provided to the control terminal of the trimmable component responsive to the determined target value.

15. The apparatus of claim 14, wherein the calibration control circuit is configured perform the test by:
measuring an up ramp time;
measuring a down ramp time; and
combining the up ramp time and the down ramp time to obtain the ramp time; and
comparing the ramp time to the target time constant to obtain the test results.

16. The apparatus of claim 15, wherein the trimmable component is a trimmable capacitor, and the calibration control circuit is configured to:
adjust the control signal to increase capacitance of the trimmable capacitor responsive to the test results indicating the ramp time is less than the target time constant; and
adjust the control signal to decrease capacitance of the trimmable capacitor responsive to the test results indicating the ramp time is more than the target time constant.

17. The apparatus of claim 14, wherein the on-chip integrator circuit is part of a resonant converter controller.

18. The apparatus of claim 14, wherein the on-chip integrator circuit is part of a low-pass filter circuit or high-pass filter circuit.

19. The apparatus of claim 14, wherein the on-chip integrator circuit is part of a phase-shift oscillator circuit.

20. The apparatus of claim 14, wherein the on-chip integrator circuit is part of a relaxation oscillator circuit.
